(19) United States
(12) Patent Application Publication
(10) Pub. No.: US 2003/0056728 A1
(43) Pub. Date: Mar. 27, 2003

(54) Method and device for depositing at least one precursor, which is in liquid or dissolved form, on at least one substrate

(76) Inventors: Johannes Lindner, Aachen-Richterich (DE); Marcus Schumacher, Kerpen (DE); Gerd Strauch, Aachen (DE); Holger Juergensen, Aachen (DE); Frank Schienle, Aacheu (DE); Piotr Strzyzewski, Herzogenrath-Kohlscheid (DE)

Correspondence Address: ST. ONGE STEWARD JOHNSTON & REENS, LLC, 986 BEDFORD STREET, STAMFORD, CT, 06905-5619, US

(21) Appl. No.: 10/205,639

(22) Filed: Jul. 25, 2002

Related U.S. Application Data
(63) Continuation of application No. PCT/DE01/00348, filed on Jan. 29, 2001.

(30) Foreign Application Priority Data
Jan. 28, 2000 (DE) 100 03 758.5

(51) Int. Cl. B05C 11/00; C23C 16/00

(52) U.S. Cl. 118/726; 118/712

(57) ABSTRACT

Disclosed is device for depositing at least one precursor, on at least one substrate, said precursor being present in the liquid or dissolved form. The inventive device comprises at least one storage container for the individual or mixed precursor/s and a reaction chamber in which the substrate/s is/are arranged, the layers being placed on said substrates. The inventive device also comprises a conveying device that conveys the precursor/s from the storage container/s to the area by means of at least one line, whereby the precursor/s are vaporized in said area. Said device further comprises a control unit which controls the conveying device. The invention is characterized in that a sensor unit is provided which detects the amount of the supplied precursors and has an output signal that is applied to the control unit as a real signal. The control unit controls the conveying device in such a way that the mass flow pertaining to the precursors has a mean predetermined value during a given time period.

This application is a continuation of pending International Application No. PCT/DE01/00348 filed Jan. 29, 2001, which designates the United States and claims priority from German Application No. 10003758.5 filed Jan. 28, 2000.

### FIELD OF THE INVENTION

The invention relates to a device for depositing at least one precursor, which is in liquid or dissolved form, on at least one substrate or wafer in accordance with the preamble of patent claim 1, and to a corresponding process.

Processes and devices of this type are used (inter alia) for the production of in particular thin films, such as semiconductor films, superconductor films, dielectric films, etc. on a substrate.

Prior Art

A process of the generic type and a device of the generic type are known (inter alia) from WO 95/02711 or WO 99/02756. It should be noted that reference is expressly made to these two documents for explanation of all the details which are not described further in the present document, for explanation of examples of the precursors which can be used, and for the nature and use of the films which can be produced on substrates or wafers using precursors.

The known devices have at least one reservoir for the precursor(s), which is/are in individual or mixed form. Furthermore, in a manner which is known per se, there is a reactor chamber, in which the substrate(s) are arranged in particular on one or more susceptors and in which the films are to be applied to the substrate.

A delivery device, which is controlled by a control unit, delivers the precursor(s) via at least one delivery line from the reservoir(s) to the region in which the precursor(s) are to be evaporated.

In the device which is known from WO 95/02711, the precursor(s) are injected periodically in the “form of droplets” into the chamber in which the deposition also takes place. The choice of the “injection time/period duration” ratio is used to set the quantity of precursors introduced per unit time in an unregulated fashion. Furthermore, the chamber in which the deposition also takes place has a carrier gas flowing through it, which entrains the precursors in “gas form” to the substrate(s) on which the film(s) are to be deposited.

The known device therefore has a number of drawbacks:

On account of the periodic injection, under certain process conditions in homogeneities may arise, which have an adverse effect on the quality of the film which is produced.

Above all, however, the actual concentration of the individual precursors is not checked, since the quantity which is evaporated is set without regulation and is not checked. A change in the quantity of a precursor which is introduced into the reactor chamber may cause the stoichiometric composition and therefore the structure of the film which is produced to change undesirably and above all disadvantageously.

### SUMMARY OF THE INVENTION

The invention is based on the object of developing a device of the generic type and a corresponding process in such a manner that flaws in the composition of the films which are produced, as may occur in the prior art, are avoided.

An inventive solution for a device is described in patent claim 1. Refinements to the invention form the subject matter of the dependent claims. A process according to the invention is described in the process claim.

According to the invention, there is a sensor unit, which records the quantity of precursors supplied per unit time and the output signal from which is applied to the control unit as an actual signal. The control unit regulates the delivery device in such a manner that the mass flow of precursors, taken as a mean over a certain period of time, has a predetermined value.

The predetermined value to which the mass flow of the precursors is set, taken as a mean over a certain period of time, may, of course, not only be a constant value, but may also be a value which is dependent on time and/or film thickness. Furthermore, the quantity of the precursor(s) which is evaporated per unit time can be deliberately influenced by means of deliberate changes in the delivery capacity and/or temperature of the precursors.

This allows not only continuous delivery, but also delivery in which the control unit switches the delivery of precursors on and off without fixedly predetermined time intervals in order to regulate the mass flow.

In order to carry out the regulating operations on the (mean) mass flow of the precursors which are provided for in accordance with the invention, the sensor unit can record the quantity of precursors supplied in the liquid phase. However, it is particularly preferable if the sensor unit records the quantities of precursors supplied in or following the evaporation region. This is because this avoids errors in the quantity of precursors introduced into the reactor chamber, which is the sole determining factor. Non-reproducible errors of this type may occur, for example, through recondensation.

In this context, it is particularly advantageous if the sensor unit records the quantity of precursors supplied in the evaporated phase in the region of a gas inlet, such as for example a showerhead, into the reactor chamber, since this allows precisely the quantity of evaporated precursors which is introduced into the reactor chamber and is no longer influenced by any possible recondensation to be measured.

The sensor unit may, for example, include weight sensors, which record the weight of the reservoirs, flow meters (in particular for the liquid phase) and/or optical sensors. Optical sensors are particularly suitable for recording the quantity of precursors in the evaporated phase which are supplied.

In a refinement of the invention, the control unit also controls the temperature of the precursors in the liquid and/or evaporated phase. In this context, it is preferable if the sensor unit records the temperature of the liquid precursor(s) in the reservoir(s) and/or in the line(s), and if the output signal(s) are applied to the control unit as actual signals, so that the temperature of the liquid precursors is subject to closed-loop control and not simply open-loop control. Suitable sensors are thermocouples, resistors or optical sensors. This prevents the mass of precursor which is evaporated per unit time from fluctuating as a result of temperature changes.

In particular, the temperature of the precursors can be controlled to a predetermined temperature, which may be dependent on the location of the precursors in the device. In other words, while they are being delivered from the reservoir to the evaporation region, the precursors can pass through a defined temperature profile.

A very wide range of devices, such as pumps, for example reciprocating pumps, gear pumps, hose pumps, etc., can be used as the delivery device. Furthermore, it is possible for the delivery device to control the pressure which the liquid is under in the reservoir. In this context, it is possible, for example, to use a pressure-resistant reservoir and to apply a pressurized inert gas to the corresponding precursor. Furthermore, it is possible to deform the container walls in such a way that the liquid flows out of the container in the desired way. The deformation may in this case take place in such a manner that at no time is a free liquid surface formed, via which the precursor could be contaminated.

There is also a very wide range of options for controlling the mass flow:

By way of example, it is possible for the control unit to control the delivery device in such a manner that it delivers the predetermined mass flow of liquid precursor. Furthermore, it is possible for the control unit to control the delivery device in such a manner that it could deliver a mass flow which is greater than the predetermined mass flow, and for there to be at least one actuator which is controlled by the control unit and which sets or restricts the liquid and/or gaseous mass flow of the respective precursor to a predetermined value. This actuator may, for example, be a valve which is provided in the delivery line for the respective precursor. In particular, the valve may be a proportional valve, the opening cross section of which controls the control unit. Furthermore, the actuator may control an injector, such as for example a nozzle, which introduces the liquid precursor into the evaporation region. The nozzle may in this case be a two-fluid or multi fluid nozzle, in which the fluid is discharged by a gas stream and the design of which is similar to that described in DE-C 41 03 413. In particular, the carrier gas may form the gas stream.

There is also a very wide range of options with regard to the design of the evaporation region:

It is preferable if there is at least one evaporation chamber, in which the precursor or at least one of the pluralities of liquid precursors is evaporated and which is connected to an inlet into the reactor chamber, such as for example a showerhead. In this case, it is also possible for the actuator to control the passage of the evaporated precursors from the evaporation chamber into the reactor chamber.

Alternatively, the injector(s) can introduce the precursors directly into the reactor chamber, so that the evaporation region is part of the reactor chamber.

In a refinement of the invention, for each precursor there is more than one evaporation region, which if appropriate may in each case be assigned at least one actuator.

If there is more than one evaporation region for each or individual precursors, it is possible for the control unit to provide open- or closed-loop control of the mass flow which is fed to each evaporation region independently of the mass flows which are fed to the other evaporation regions for the same precursor. This allows the distribution of the precursors in the reactor chamber to be set deliberately. In this context, it is preferable if the sensor unit records the distribution of the evaporated precursors in the reactor chamber. In particular, the output signal from the sensor unit may be applied to the control unit for regulation of the mass flow fed to each of the evaporation regions.

In a further configuration of the invention, there is a temperature-control unit which sets the temperature of the liquid in the reservoir(s), in the feed line(s), in the actuator(s) and/or in the evaporation region(s) to predetermined values. The temperature-control unit may have a cooling unit, which cools the precursor(s) upstream of the evaporation region to a temperature which is lower than the evaporation temperature. Of course, it is possible not only to set a constant temperature, but also temperature programs and/or temperature profiles along the delivery path.

It is particularly preferable if the temperature-control unit, at a given pressure in the reactor chamber, sets a temperature profile which is such that the temperature in the evaporation region of the precursor(s) is above the evaporation temperature. For this purpose, it is possible for surfaces whose temperature can be controlled to be disposed in the evaporation region. The surfaces can be directly or indirectly heated, electrically by means of a resistance heater or by irradiation or in any other way.

If more than one precursor is being used, the precursors may be present in mixed form in the reservoirs and/or various precursors which are each stored in separate reservoirs may be mixed in accordance with a predetermined mixing ratio in the liquid or gaseous state in the evaporator region, in the region of the gas inlet (showerhead) into the reactor chamber and/or only in the reactor chamber. It is also possible to “switch over” between different reservoirs in order for different films to be produced.

Of course, it is not only possible to use liquid precursors. It is additionally possible for substances which are in gas form to be used as film-forming substances. For this purpose, at least one inlet for a carrier gas and/or a process gas may be provided in the reactor chamber and/or in the evaporation region.

### BRIEF DESCRIPTION OF THE DRAWINGS

The invention is described below by way of example with reference to the drawing, in which:

FIG. 1 shows the basic structure of a device in which the invention can be used,

FIG. 2 shows an example of the structure of a reactor chamber,

FIGS. 3a and 3b show the design of a sensor unit which is provided in accordance with the invention.

### DESCRIPTION OF AN EXEMPLARY EMBODIMENT

FIG. 1 shows the basic structure of a device for depositing films on a substrate. The device has a reactor chamber 1, in which one or more substrates (not shown), on which at least one film is to be deposited using the process according to the invention, are disposed on (at least) one susceptor 2.

For this purpose, the reactor chamber 1 has (in the exemplary embodiment shown and without restriction with regard to the number of possible injectors) three injectors 3, by means of which (identical or different) precursors which are in liquid or dissolved form are delivered into one or more evaporation regions 4 (which are only diagrammatically illustrated). In the exemplary embodiment which is shown, the precursors, which are in gas form following the evaporation region 4, are introduced via outlets 5 (which are likewise only diagrammatically illustrated), which may, for example, be what are known as showerheads, into the interior of the reactor chamber 1 in such a manner that they are distributed over the substrate(s) disposed on the susceptor 2 in such a way that a homogeneous film is formed on the substrate(s) (for example wafers). In addition, there is (at least) one gas outlet 6, through which a carrier gas or a process gas can enter the interior of the reactor chamber 1. The gases located in the reactor chamber are discharged again from the reactor chamber 1 via an outlet 9.

For each of the precursors or precursor mixtures which are to be delivered to (at least) one of the injectors 3, there is a storage tank 6, which is connected, via a line 7 with an immersion pipe which projects into the liquid 6′ located in the storage tank 6, to the respective injector(s) 3. It is possible for one injector to be successively connected to different storage tanks. In order for the respective precursor 6′ to be delivered from the storage tank 6 which is in each case connected to the injector into the line 7, there is a pressure pipe 8, via which a pressure, which can be controlled by a control unit (not shown), is applied to the liquid 6′ in the storage tank, so that the liquid is delivered through the line 7 to the respective injector 3 in a defined delivery quantity per unit time. Of course, however, other delivery devices are also possible.

The basic structure of the device which has been described above is known in principle.

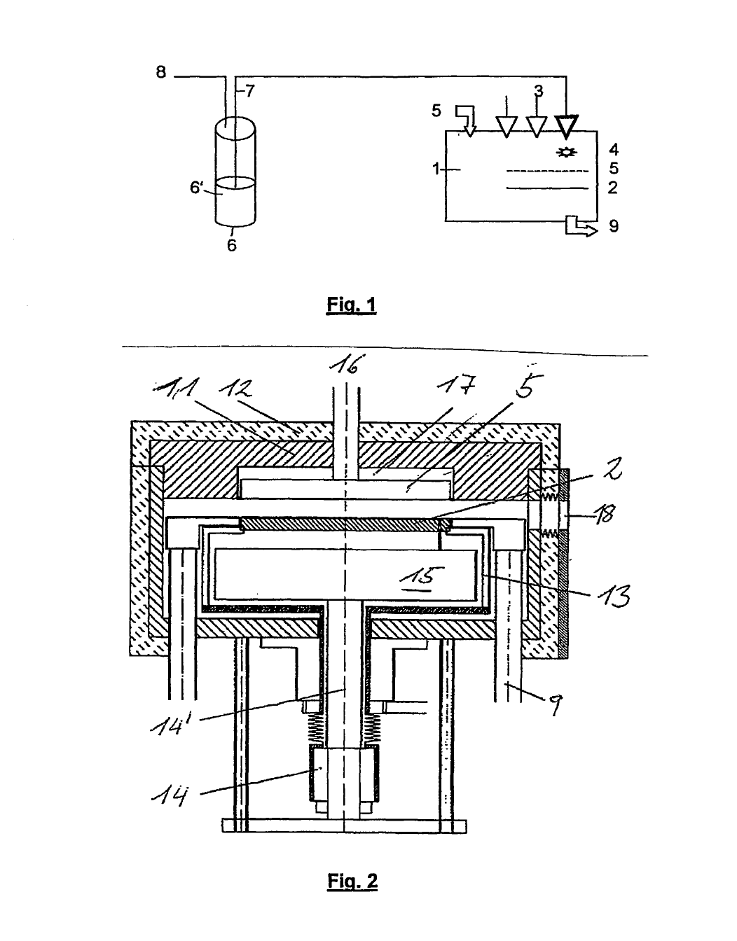

FIG. 2 shows, by way of example, a (possible) structure of the reactor chamber 1. The susceptor or the wafer holder 2 is disposed on a susceptor support 13 in a housing 11 with thermal insulation 12. In the exemplary embodiment shown, the support 13 is rotated by a rotary device 14, so that it rotates together with the susceptor 2 about the axis of rotation 14′. In addition, what are known as planets may be disposed in a manner known per se on the susceptor, which planets are driven, for example by means of a gas stream (“gasfoil”), to rotate about an axis which is at a distance from the axis of rotation 14′ and on which the substrates (also not shown in FIG. 2) are then disposed. Reactors of this type are also known as planetary reactors and are produced by Aixtron AG, Aachen, Germany. Reference is made to the design of these known planetary reactors.

However, it should be expressly pointed out that the design of the susceptor(s) is not crucial to the invention and that it is also possible, of course, to use reactor chambers of different designs: for example, it is possible to use horizontal reactors, in which the susceptor(s) do not rotate, or vertical reactors, in which the substrates are disposed vertically.

In a manner which is known per se, the reactor 1, which is illustrated by way of example as a possible reactor chamber in FIG. 2, has a heater 15, for example one or more IR lamps, for the susceptor(s) 2 and also, if appropriate, a temperature-control system (not shown in more detail) for the housing 11, by means of which the housing 11 can be set to a defined temperature and in particular to a (locally variable) predetermined temperature profile.

Furthermore, there is a gas inlet system, which is only diagrammatically indicated in FIG. 2 for one or more precursors (which are already in gas form). This gas inlet system has a feed pipe 16, which connects the evaporator or evaporation region 4 (not shown in FIG. 2) to a showerhead 5, which is only diagrammatically indicated and from which the respective precursor(s) enter the interior of the reactor chamber 1 with a flow profile which leads to a homogeneous distribution of the individual atoms or compounds on the wafer surface and therefore to the formation of a homogeneous film.

If two or more precursors are being used, the precursors and if appropriate process or carrier gases may be mixed in the interior of the showerhead—this requires a plurality of supply tubes—or as early as in the evaporation region or even in the storage tank or in the liquid phase—for example by means of static mixing elements—so that the (already) mixed precursors (in gas form) and/or process and/or carrier gases are fed through a single supply tube 16 to the showerhead 5 (of which there is in this case only one).

Alternatively, if a plurality of precursors is being used, it is possible to use a plurality of supply tubes 16, which connect a plurality of separate evaporation regions 4 to one or more showerheads 5. If a plurality of showerheads is being used, these showerheads may then be designed in such a way that their gas outlet openings are disposed in an “interleaved” manner toward the interior of the reactor chamber 1, so that the individual gaseous precursors (and any further process gases) are only mixed in the interior of the reactor chamber 1.

In the exemplary embodiment which is shown, above the showerhead 5 there is a volume 17 which can be used in various ways:

For example, the volume 17 can be used for introduction of a gas. The conduction of heat between the showerhead 5 and the temperature-controlled housing 11 can be set by means of the gas pressure in the volume 17 in such a way that the showerhead 5, which also exchanges thermal energy with the process gas(es), adopts a temperature which is preferred with regard to the process conditions.

As an alternative (or in addition), process and/or carrier gases can be introduced into the volume 17 and then enter into the interior of the reactor chamber 1 at the edges of the showerhead—if appropriate via suitable throttles.

A combination of all the possibilities which have been listed above can also be used:

For example, it is possible for individual precursors already to have been mixed in a defined storage tank, and for further precursors, which are stored individually in storage tanks, to be “admixed” in liquid form—for example using the static mixing elements which have been mentioned above—and/or in the evaporation region and/or in the showerhead and/or in the reactor chamber. It is also possible for process and/or carrier gases to be admixed at any location at which the precursors are already in gas form. Furthermore, it is possible to switch between storage tanks containing different precursors, so that different precursors are evaporated in succession using one and the same injector, leading to different films being formed.

Irrespective of the precise design of the device, it is necessary to accurately maintain the concentration of the individual precursors in the reactor chamber above the substrate(s) or wafer(s).

According to the invention, it is ensured that the concentration of the individual precursors required is maintained as a result of the mass flow of the precursors being subjected to closed-loop control instead of simply open-loop control:

For this purpose, there is a sensor unit which records the quantity of precursors supplied and the output signal from which is applied as an actual signal to the control unit in order for the mass flow to be regulated.

In this case, the sensor unit can record the quantity of precursors supplied in the liquid phase.

However, it is particularly advantageous if the sensor unit records the quantity of precursors supplied in the evaporated phase as close as possible to the substrate, since the concentration errors in the film produced as a result of recondensation of one or more precursors are then as low as possible.

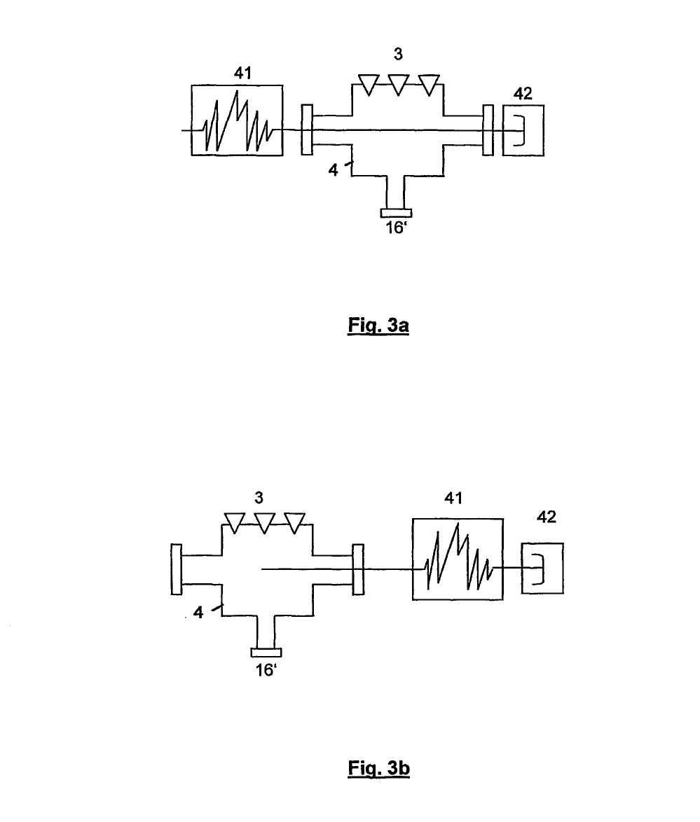

For this purpose, the sensor unit may be disposed in the region of a gas inlet, such as for example the showerhead 5, into the reactor chamber 1. In the case of the reactor chamber 1 illustrated in FIG. 2, for this purpose there is a window 18 on the side, which, for example, allows optical determination of the concentration of the individual precursors, for example in the manner described in connection with FIGS. 3a and 3b. This procedure has the advantage that precisely the quantity of evaporated precursors which is introduced into the reactor chamber 1 is recorded.

Alternatively, it is possible to record the quantity of precursors evaporated in the evaporator region(s) 4. This may be achieved, for example, by means of an—optionally positionally resolved—pressure measurement or another process, for example using ellipsometers.

However, optical measurements are particularly advantageous, as illustrated by way of example in FIGS. 3a and 3b.

FIGS. 3a and 3b diagrammatically depict an evaporator region 4, which is designed as a separate chamber. The abovementioned injectors 3 open out into the evaporator chamber 4. On the opposite side, there is an outlet 16′ which is connected, for example, to the line 16 (FIG. 2) and through which the evaporated precursor(s) emerge from the chamber.

In order for the quantity of the evaporated precursors to be recorded, an interferometer 41 and a detector 42 are provided, which form a FTIR sensor unit and in the exemplary embodiment shown in FIG. 3a are disposed on both sides of the chamber 4 and in the exemplary embodiment shown in FIG. 3b are disposed on one side of the chamber 4.

In both cases, accurate recording of the quantity of precursor which is present in the chamber 4 is possible by interferometry.

The output signal from the detector 42 is applied to the control unit (not shown) in order for the mass flow of the precursor(s) to be regulated.

In addition, the wall of the evaporator chamber 4 may be provided with a heater and temperature sensors, so that the wall can be regulated to a temperature which is optimum for the procedure.

The invention has been described above with reference to an exemplary embodiment and without restriction to the general idea of the invention as established by the claims.

Irrespective of the wording of the claims, purely by way of precaution the claiming of further inventive ideas which are not included in the claims is claimed.

1. A device for depositing at least one precursor, which is in liquid or dissolved form, on at least one substrate, having
at least one reservoir (6) for the precursor(s) (6′), which is/are in individual or mixed form,
a reactor chamber (1), in which the substrate(s), to which at least one film is to be applied, are disposed,
a delivery device (8), which delivers the precursor(s) (6′) via at least one line (7) from the reservoir(s) (6) to at least one region (4) in which the precursor(s) (6′) are to be evaporated, and
a control unit which controls the delivery device (8), characterized in that there is a sensor unit (41, 42), which records the quantity of precursors supplied per unit time and the output signal from which is applied to the control unit as an actual signal, and
in that the control unit regulates the delivery device (8) in such a manner that the mass flow of precursors, taken as a mean over a defined period of time, has a predetermined value.

2. The device according to claim 1, characterized in that the control unit switches the delivery of precursors on and off, without fixedly predetermined time intervals, in order to regulate the mass flow.

3. The device according to claim 1, characterized in that the control unit effects continuous delivery of precursors in order to regulate the mass flow.

4. The device according to one of claims 1 to 3, characterized in that the delivery device is a pump.

5. The device according to one of claims 1 to 3, characterized in that the delivery device (8) controls the pressure which the liquid (6′) is under in the reservoir (6).

6. The device according to one of claims 1 to 5, characterized in that the control unit controls the delivery device in order to regulate the mass flow.

7. The device according to one of claims 1 to 5, characterized in that the control unit controls the delivery device in such a manner that it could deliver a mass flow which is greater than the predetermined mass flow, and
in that there is at least one actuator which is controlled by the control unit in order for the mass flow to be regulated and which sets the mass flow of the respective precursor to a predetermined value.

8. The device according to claim 7, characterized in that the actuator is a valve which is provided in the line for the respective precursor.

9. The device according to claim 8, characterized in that the valve is a proportional valve, the opening cross section of which controls the control unit.

10. The device according to claim 7, characterized in that the actuator controls an injector which introduces the liquid precursor into the evaporation region.

11. The device according to one of claims 1 to 10, characterized in that there is at least one evaporation chamber (4), in which the precursor (6′) or at least one of the plurality of liquid precursors evaporates, and which is connected to at least one inlet into the reactor chamber (1), such as for example a showerhead (5).

12. The device according to claim 11, characterized in that the actuator controls the passage of the evaporated precursors from the evaporation chamber into the reactor chamber.

13. The device according to one of claims 1 to 11, characterized in that the injector(s) introduce the precursor(s) directly into the reactor chamber, so that the evaporation region is part of the reactor chamber.

14. The device according to one of claims 1 to 13, characterized in that the injectors are two-fluid or multi fluid nozzles, and in that one fluid is the carrier gas.

15. The device according to one of claims 1 to 14, characterized in that the sensor unit records the quantity of precursors supplied in the liquid phase.

16. The device according to one of claims 1 to 14, characterized in that the sensor unit records the quantity of precursors supplied in or following the evaporation region.

17. The device according to claim 16, characterized in that the sensor unit records the quantity of precursors supplied in the evaporated phase in the region of a gas inlet into the reactor chamber, such as for example the showerhead (5).

18. The device according to one of claims 1 to 17, characterized in that the control unit controls the temperature of the precursor(s) to values which can in each case be predetermined, if appropriate on a local basis.

19. The device according to claim 18, characterized in that the sensor unit records the temperature of the liquid precursor(s) in the reservoir(s) and/or in the line(s).

20. The device according to claim 19, characterized in that the output signal from the temperature sensor unit is applied to the control unit as an actual signal.

21. The device according to claim 19 or 20, characterized in that the control unit controls the temperature of the precursors to in each case predetermined values.

22. The device according to one of claims 1 to 21, characterized in that there is more than one evaporation region for each precursor.

23. The device as claimed in claim 22, characterized in that the control unit subjects the mass flow which is fed to each evaporation region to open- or closed-loop control independently of the mass flows which are fed to the other evaporation regions for the same precursor.

24. The device according to one of claims 1 to 23, characterized in that the sensor unit records the distribution of the evaporated precursors in the reactor chamber.

25. The device according to claim 24, characterized in that the output signal from the sensor unit is applied to the control unit for regulation of the mass flow which is fed to each of the evaporation regions.

26. The device according to one of claims 1 to 25, characterized in that a temperature-control unit is provided, which sets the temperature of the liquid in the reservoir(s), in the feed line(s), in the actuator(s) and/or in the evaporation region(s) to predetermined values.

27. The device according to claim 26, characterized in that the temperature-control unit has a cooling unit which cools the precursor(s) upstream of the evaporation region to a temperature which is lower than the evaporation temperature at the pressure in the evaporation region.

28. The device according to claim 26 or 27, characterized in that the temperature-control unit, at a given pressure in the reactor chamber, sets a temperature profile which is such that the temperature in the evaporation region of the precursor(s) is above the evaporation temperature for the corresponding pressure in the evaporation region.

29. The device according to claim 28, characterized in that surfaces whose temperature can be controlled are disposed in the evaporation region.

30. The device according to one of claims 1 to 29, characterized in that, when more than one precursor is being used, the precursors are present in mixed form in the reservoirs and/or various precursors, which are each stored in separate reservoirs, are mixed in accordance with a predetermined mixing ratio in the liquid state in the evaporator region, in the region of the gas inlet (showerhead) into the reactor chamber and/or only in the reactor chamber.

31. The device according to claim 30, characterized in that there are static mixing elements which effect mixing of the individual liquid precursors.

32. The device according to one of claims 1 to 31, characterized in that at least one inlet for a carrier gas and/or a process gas is provided in the reactor chamber and/or the evaporation region(s).

33. The device according to one of claims 5 to 32, characterized in that the precursor is disposed in a deformable container which is in a pressure-resistant vessel, and in that the container, for delivery of the precursor, is acted on by a gas located in the vessel in such a manner that as a result there is no free liquid surface.

34. A process for depositing at least one precursor, which is in liquid or dissolved form, on at least one substrate, in which the precursors, which are in individual or mixed form, are delivered by a delivery device via at least one line into at least one evaporation region, so that they form the films on the substrate arranged in a reactor chamber, characterized in that the quantity of precursors supplied is recorded, and in that the mass flow of the precursors, taken as a mean over a certain period of time, is set to a predetermined value.

35. The use of the process according to claim 34 for producing thin films on substrates.
